(19) United States
(12) Patent Application Publication
(10) Pub. No.: US 2024/0357771 A1
(43) Pub. Date: Oct. 24, 2024

(54) COMBINED AIR-COOLING AND LIQUID-COOLING REFRIGERATION SYSTEM AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shun WANG, Zhangjiakou City (CN)

(21) Appl. No.: 18/619,428

(22) Filed: Mar. 28, 2024

(30) Foreign Application Priority Data
Apr. 18, 2023 (CN) 202310416544.5

(51) Int. Cl. H05K 7/20

(52) U.S. Cl. CPC H05K 7/20745; H05K 7/20272; H05K 7/20772

(57) ABSTRACT

The present disclosure discloses a combined air-cooling and liquid-cooling refrigeration system and a data center. The combined air-cooling and liquid-cooling refrigeration system at least includes a closed area, a combined device group, a circulating liquid-cooling system, and a plurality of air cooling devices. The combined device group and the circulating liquid-cooling system are installed inside the closed area, and the plurality of air cooling devices are installed outside the closed area. The combined device group includes a first device group and a second device group, and a closed hot aisle is formed between the first device group and the second device group. Both the first device group and the second device group include a plurality of server cabinets. The circulating liquid-cooling system is connected to primary heating sources of the plurality of server cabinets.

### CROSS REFERENCE TO RELATED APPLICATION

This application claims priority to Chinese Patent Application No. 202310416544.5, titled “COMBINED AIR-COOLING AND LIQUID-COOLING REFRIGERATION SYSTEM AND DATA CENTER” and filed to the China National Intellectual Property Administration on Apr. 18, 2023, the entire contents of which are incorporated herein by reference.

### TECHNICAL FIELD

The present disclosure relates to the field of data centers, and more particularly, to a combined air-cooling and liquid-cooling refrigeration system and a data center.

### BACKGROUND

In recent years, with the rapid development of data center related technologies, centralized configuration of computer room servers, together with servers and storage systems, has changed, and their power density and heat density have increased rapidly, resulting in a surge in heat generated by data centers, which leads to higher and higher requirements of the data centers for refrigeration systems.

For the existing data centers, using single air-cooling air conditioners or single liquid-cooling radiators can no longer meet the refrigeration requirements of the high-density data centers.

### SUMMARY

An objective of the present disclosure is to provide a combined air-cooling and liquid-cooling refrigeration system and a data center, to improve heat dissipation efficiency.

To achieve the above objective, in one aspect the present disclosure provides a combined air-cooling and liquid-cooling refrigeration system, which at least includes a closed area, a combined device group, a circulating liquid-cooling system, and a plurality of air cooling devices. The combined device group and the circulating liquid-cooling system are installed inside the closed area, and the plurality of air cooling devices are installed outside the closed area.

The combined device group includes a first device group and a second device group, and a closed hot aisle is formed between the first device group and the second device group.

Both the first device group and the second device group include a plurality of server cabinets.

The circulating liquid-cooling system is connected to primary heating sources of the plurality of server cabinets to carry out liquid-cooling heat dissipation on the primary heating sources of the plurality of server cabinets.

The plurality of air cooling devices are connected to an air outlet of an exhaust duct of the closed hot aisle to refrigerate hot air discharged from the closed hot aisle to carry out air-cooling heat dissipation on the plurality of server cabinets.

Alternatively, the circulating liquid-cooling system and the plurality of server cabinets positioned in the same device group are arranged side by side.

Alternatively, the first device group and the second device group are arranged in parallel at intervals.

A partition board is respectively provided between an end of the first device group and an end of the second device group, such that the closed hot aisle is formed between the first device group, the second device group, and the two partition boards.

Alternatively, the circulating liquid-cooling system includes at least a liquid inlet pipe, a liquid outlet pipe, and a plurality of liquid-cooling shunts.

The liquid inlet pipe and the liquid outlet pipe are connected to an external cooling device to refrigerate circulating liquids in the liquid inlet pipe and the liquid outlet pipe.

One end of each of the plurality of liquid-cooling shunts is communicated with the liquid inlet pipe, and other end of each of the plurality of liquid-cooling shunts is communicated with the liquid outlet pipe.

Each of the plurality of liquid-cooling shunts is connected in series with one end of a heat transfer component, and other end of the heat transfer component comes into contact with the primary heating source of the server cabinet.

Alternatively, the external cooling device includes one or more of a cooling tower, a dry cooler, and an evaporator.

Alternatively, the air cooling device is connected to a first solenoid valve, and the circulating liquid-cooling system is connected to a second solenoid valve to control the external cooling device to operate independently of the circulating liquid-cooling system.

Alternatively, the circulating liquid-cooling system also includes a heat exchanger; and the external cooling device exchanges heat with the circulating liquids in the liquid inlet pipe and the liquid outlet pipe through the heat exchanger.

Alternatively, the heat exchanger is provided at one end of the first device group and one end of the second device group; and an array cabinet is provided at other end of the first device group and other end of the second device group.

Alternatively, a plurality of the combined device groups are provided, and the plurality of combined device groups are arranged in the closed area in a linear array.

To achieve the above objective, another aspect of the present disclosure also provides a data center, which comprises at least a plurality of device rooms, where each of the plurality of device rooms is provided with the combined air-cooling and liquid-cooling refrigeration system.

In the above technical solutions, the circulating liquid-cooling system is connected to a main heating source of the server cabinet to carry out liquid cooling on the main heating source of the server cabinet. Furthermore, the combined device group is arranged within the closed area, and a closed hot aisle is formed between the first device group and the second device group. In this way, hot air generated by the server cabinet in the closed hot aisle may be cooled by the air cooling device. Thus, a cold environment is formed in the closed area to dissipate heat from rest of the heating sources of the server cabinet. In this way, heat is dissipated from the main heating source by means of liquid cooling, and heat is dissipated from the rest of heating sources by means of air cooling, such that air cooling and liquid cooling is integrated, which can effectively improve heat dissipation efficiency and meet heat dissipation requirements.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a combined air-cooling and liquid-cooling refrigeration system according to an embodiment of the present disclosure; and

FIG. 2 is a schematic diagram showing a partial structure of FIG. 1.

### REFERENCE NUMERALS IN THE ACCOMPANYING DRAWINGS

closed area 1; combined device group 2; circulating liquid-cooling system 3; air cooling device 4; external cooling device 5; first device group 21; second device group 22; closed hot aisle 23; partition board 24; server cabinet 212; liquid inlet pipe 31; liquid outlet pipe 32; liquid-cooling shunt 33; heat exchanger 34; and array cabinet 35.

### DETAILED DESCRIPTION

Detailed description of the embodiments of the present disclosure will further be made below with reference to the accompanying drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

Centralized configuration of computer room servers, together with servers and storage systems, has changed, and their power density and heat density have increased rapidly, resulting in a surge in heat generated by data centers, which leads to higher and higher requirements of the data centers for refrigeration systems.

The existing data centers use single air-cooling air conditioners or single liquid-cooling radiators for refrigeration, but their heat dissipation effects can no longer meet the refrigeration requirements of the high-density data centers. Therefore, the present disclosure provides a combined air-cooling and liquid-cooling refrigeration system and a data center, which integrates air-cooling and liquid-cooling refrigeration to improve the heat dissipation efficiency.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

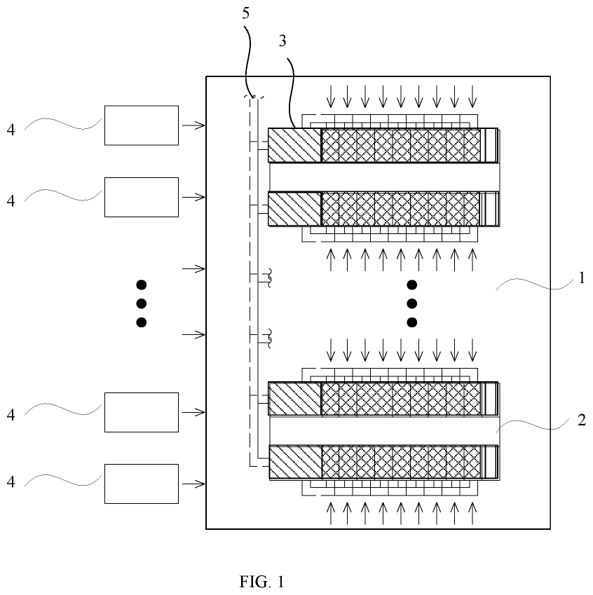

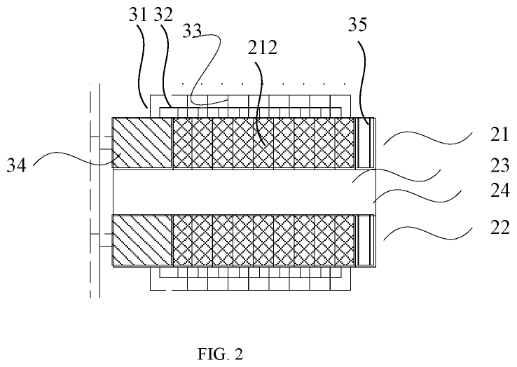

As shown in FIG. 1 and FIG. 2, in an implementable embodiment, a combined air-cooling and liquid-cooling refrigeration system may at least include a closed area 1, a combined device group 2 and a circulating liquid-cooling system 3, where the combined device group 2 and the circulating liquid-cooling system 3 are installed within the closed area 1. The combined device group 2 includes a first device group 21 and a second device group 22, and a closed hot aisle 23 is formed between the first device group 21 and the second device group 22, such that heat generated in the first device group 21 and the second device group 22 flows into the closed hot aisle 23.

Both the first device group 21 and the second device group 22 may include a plurality of server cabinets 212. The server cabinets 212 may be some devices such as commonly used server cabinets that generate a large amount of heat during normal operation. The air cooling device 4 is installed outside the closed area 1 and is configured to refrigerate hot air flowing out of the closed hot aisle 23, thereby maintaining a cold environment in the closed area 1 to dissipate heat from rest of heating components inside the server cabinet 212, such as power distribution cables, power distribution devices, and other power distribution devices inside the server cabinet 212. The circulating liquid-cooling system 3 is connected to primary heating sources (such as CPU, GPU, etc.) of the plurality of server cabinets 212 to carry out liquid-cooling heat dissipation on the primary heating sources (such as the CPU) of the server cabinets 212, and the plurality of air cooling devices refrigerate hot air discharged from the closed hot aisle 23 to carry out air-cooling heat dissipation on the server cabinets 212.

In practical use, the combined air-cooling and liquid-cooling refrigeration system may be used for heat dissipation of the server cabinets 212 in data centers. Correspondingly, the air cooling device 4 may be an inter-row air conditioner. The circulating liquid-cooling system 3 is configured to dissipate heat from the CPU and the GPU in the server cabinet. Heat generated by rest of the heating components in the server cabinets 212 of the combined device group 2 may cause temperature of air to rise, thereby forming hot air, which may enter the closed hot aisle 23. The air cooling device 4 may blow cold air into the closed hot aisle 23 to cool down the hot air. In this way, air temperature of the entire server cabinets 212 is reduced, and rest of the heating components of the server cabinets 212 are cooled down.

It should be pointed out that although in the above practical application, the combined air-cooling and liquid-cooling refrigeration system of the present disclosure is used in the data center to dissipate heat from the server cabinets 212, but it is not limited thereto. The combined air-cooling and liquid-cooling refrigeration system of the present disclosure may also be applied to other devices other than the data center, to carry out efficient heat dissipation and cooling for the other devices. In addition, the primary heating sources defined in the present disclosure may be determined in advance by those skilled in the art, which may be parts or positions with maximum heat generation in the server cabinets 212.

In the above technical solutions, the circulating liquid-cooling system is connected to a main heating source of the server cabinet to carry out liquid cooling on the main heating source of the server cabinet. Furthermore, the combined device group is arranged within the closed area, and a closed hot aisle is formed between the first device group and the second device group. In this way, the hot air generated by the server cabinet in the closed hot aisle may be cooled by the air cooling device. Thus, a cold environment is formed in the closed area to dissipate heat from rest of the heating sources of the server cabinet. In this way, heat is dissipated from the main heating source by means of liquid cooling, and heat is dissipated from the rest of heating sources by means of air cooling, such that air cooling and liquid cooling is integrated, which can effectively improve heat dissipation efficiency and meet heat dissipation requirements.

In a possible embodiment, more efficient heat dissipation is provided. As shown in FIG. 2, the circulating liquid-cooling system 3 and the plurality of server cabinets 212 positioned in the same device group are arranged side by side. In this way, the circulating liquid-cooling system 3 can rapidly absorb heat of the CPU/GPU in the server cabinets 212, to rapidly carry out liquid-cooling heat dissipation on the server cabinets 212.

Formation of a specific structure of the closed hot aisle 23 is described below. In a possible embodiment, the first device group 21 and the second device group 22 are arranged in parallel at intervals. A partition board 24 is respectively provided between an end of the first device group 21 and an end of the second device group 22, such that the closed hot aisle 23 is formed between the first device group 21, the second device group 22, and the two partition boards 24. Of course, in actual use, a bottom surface of the first device group 21 and a bottom surface of the second device group 22 may be provided with a floor plate, and a top surface of the first device group 21 and a top surface of the second device group 22 may be provided with a cover plate, to close upper and lower ends of the closed hot aisle 23.

As for the specific structure of the circulating liquid-cooling system 3, in an implementable embodiment, referring to FIG. 2, the circulating liquid-cooling system 3 may at least include a liquid inlet pipe 31, a liquid outlet pipe 32, and a plurality of liquid-cooling shunts 33. The liquid inlet pipe 31 and the liquid outlet pipe 32 are connected to an external cooling device 5 to refrigerate circulating liquids in the liquid inlet pipe 31 and the liquid outlet pipe 32. One end of each of the plurality of liquid-cooling shunts 33 is communicated with the liquid inlet pipe 31, and other end of each of the plurality of liquid-cooling shunts 33 is communicated with the liquid outlet pipe 32, such that circulating cold water in the liquid inlet pipe 31 enters the liquid-cooling shunt 33, and after heat exchange, hot water in the liquid-cooling shunt 33 flows into the liquid outlet pipe 32, thereby implementing liquid cooling circulation.

Formation of the specific structure of the closed hot aisle 23 is described below. In a possible embodiment, the external cooling device 5 includes one or more of a cooling tower, a dry cooler, and an evaporator.

When the external cooling device 5 is the cooling tower, the hot water discharged from the circulating liquid-cooling system 3 may be condensed by the condenser and a precooling section in the cooling tower. The condensed circulating cooling water flows back into the circulating liquid-cooling system 3 under gravity.

When the external cooling device 5 is the dry cooler, the hot water discharged from the circulating liquid-cooling system 3 may be cooled down by the dry cooler to lower its temperature. The cooled circulating cooling water flows back into the circulating liquid-cooling system 3 under gravity.

When the external cooling device 5 is the evaporator, the hot water may be vaporized into steam and absorb heat. The circulating vapor flows back into the circulating liquid-cooling system 3 under gravity.

In a possible embodiment, the air cooling device 4 is connected to a first solenoid valve, and the circulating liquid-cooling system 3 is connected to a second solenoid valve. When the first solenoid valve is turned on, the air cooling device 4 operates separately to dissipate heat from the CPU and the GPU in the server cabinet 212. When the second solenoid valve is turned on, the circulating liquid-cooling system 3 operates separately to dissipate heat from other heating components inside the server cabinet 212. In this way, users' needs for separate liquid-cooling or air-cooling heat dissipation can be met.

It should be noted that the specific structure of the heat transfer component 4 described above is only one embodiment of the present disclosure, but is not limited thereto. The heat transfer component 4 also may be a circulating conduit that guides the liquid into the server cabinet 212, such that the liquid attaches/covers (or directly soaks) the primary heating source, to dissipate heat from the primary heating source of the server cabinet 212.

In a possible embodiment, the circulating liquids in the liquid inlet pipe 31, the liquid outlet pipe 32 and the liquid-cooling shunt 33 are prevented from being contaminated, thereby preventing internal blockage. In a possible embodiment, the circulating liquid-cooling system 3 further includes a heat exchanger 34. The external cooling device 5 exchanges heat with the circulating liquids in the liquid inlet pipe 31 and the liquid outlet pipe 32 through the heat exchanger 34.

In actual use, the heat exchanger 34 may be a plate heat exchanger. The plate heat exchanger has outer circulation inlet and outlet and inner circulation inlet and outlet, where the outer circulation inlet and outlet are connected in series with a circulation loop of the external cooling device 5 to form an outer circulation, and the inner circulation inlet and outlet are connected in series with the liquid inlet pipe 31 and the liquid outlet pipe 32 to form an inner circulation. In this way, the liquid in the inner circulation and the liquid in the outer circulation are separated to avoid pollution. Meanwhile, the liquid in the outer circulation may exchange heat with the liquid in the inner circulation through the heat exchanger 34, thereby achieving heat dissipation of the primary heating source of the server cabinet 212.

Further, the heat exchanger 34 is provided at one end of the first device group 21 and one end of the second device group 22. An array cabinet 35 is provided at other end of the first device group 21 and other end of the second device group 22, where the array cabinet 35 is configured to supply power to the corresponding device group. By distributing the heat exchanger 34 and the array cabinet 35 at two ends of the device group, adverse effects of liquid leakage of the heat exchanger 34 on the array cabinet 35 can be avoided to a certain extent.

Further, there may be a plurality of combined device groups 2, and the plurality of combined device groups 2 are arranged in the closed area 1 in a linear array, such that the air cooling devices 4 of adjacent two device groups 2 can refrigerate each other.

Based on the same inventive concept, the present disclosure also provides a data center, which includes at least a plurality of device rooms, where each of the plurality of device rooms is provided with the combined air-cooling and liquid-cooling refrigeration system.

It is to be particularly point out that reference may be made to the above contents for the specific structure of applying the combined air-cooling and liquid-cooling refrigeration system to the data center, which is not to be described in detail here.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A combined air-cooling and liquid-cooling refrigeration system at least comprising a closed area, a combined device group, a circulating liquid-cooling system, and a plurality of air cooling devices, wherein the combined device group and the circulating liquid-cooling system are installed inside the closed area, and the plurality of air cooling devices are installed outside the closed area;
the combined device group comprises a first device group and a second device group, and a closed hot aisle is formed between the first device group and the second device group;
both the first device group and the second device group comprise a plurality of server cabinets;
the circulating liquid-cooling system is connected to primary heating sources of the plurality of server cabinets to carry out liquid-cooling heat dissipation on the primary heating sources of the plurality of server cabinets; and
the plurality of air cooling devices are connected to an air outlet of an exhaust duct of the closed hot aisle to refrigerate hot air discharged from the closed hot aisle to carry out air-cooling heat dissipation on the plurality of server cabinets.

2. The combined air-cooling and liquid-cooling refrigeration system according to claim 1, wherein the circulating liquid-cooling system and the plurality of server cabinets positioned in the same device group are arranged side by side.

3. The combined air-cooling and liquid-cooling refrigeration system according to claim 2, wherein the first device group and the second device group are arranged in parallel at intervals; and
a partition board is respectively provided between an end of the first device group and an end of the second device group, such that the closed hot aisle is formed between the first device group, the second device group, and the two partition boards.

4. The combined air-cooling and liquid-cooling refrigeration system according to claim 3, wherein the circulating liquid-cooling system comprises at least a liquid inlet pipe, a liquid outlet pipe, and a plurality of liquid-cooling shunts;
the liquid inlet pipe and the liquid outlet pipe are connected to an external cooling device to refrigerate circulating liquids in the liquid inlet pipe and the liquid outlet pipe;
one end of each of the plurality of liquid-cooling shunts is communicated with the liquid inlet pipe, and other end of each of the plurality of liquid-cooling shunts is communicated with the liquid outlet pipe; and
each of the plurality of liquid-cooling shunts is connected in series with one end of a heat transfer component, and other end of the heat transfer component comes into contact with the primary heating source of the server cabinet.

5. The combined air-cooling and liquid-cooling refrigeration system according to claim 4, wherein the external cooling device comprises one or more of a cooling tower, a dry cooler, and an evaporator.

6. The combined air-cooling and liquid-cooling refrigeration system according to claim 4, wherein the air cooling device is connected to a first solenoid valve, and the circulating liquid-cooling system is connected to a second solenoid valve to control the external cooling device to operate independently of the circulating liquid-cooling system.

7. The combined air-cooling and liquid-cooling refrigeration system according to claim 6, wherein the circulating liquid-cooling system further comprises a heat exchanger; and
the external cooling device exchanges heat with the circulating liquids in the liquid inlet pipe and the liquid outlet pipe through the heat exchanger.

8. The combined air-cooling and liquid-cooling refrigeration system according to claim 7, wherein the heat exchanger is provided at one end of the first device group and one end of the second device group; and
an array cabinet is provided at other end of the first device group and other end of the second device group.

9. The combined air-cooling and liquid-cooling refrigeration system according to claim 1, wherein a plurality of the combined device groups are provided, and the plurality of combined device groups are arranged in the closed area in a linear array.

10. A data center comprising at least a plurality of device rooms, wherein each of the plurality of device rooms is provided with a combined air-cooling and liquid-cooling refrigeration system, the combined air-cooling and liquid-cooling refrigeration system at least comprising a closed area, a combined device group, a circulating liquid-cooling system, and a plurality of air cooling devices, wherein the combined device group and the circulating liquid-cooling system are installed inside the closed area, and the plurality of air cooling devices are installed outside the closed area;
the combined device group comprises a first device group and a second device group, and a closed hot aisle is formed between the first device group and the second device group;
both the first device group and the second device group comprise a plurality of server cabinets;
the circulating liquid-cooling system is connected to primary heating sources of the plurality of server cabinets to carry out liquid-cooling heat dissipation on the primary heating sources of the plurality of server cabinets; and
the plurality of air cooling devices are connected to an air outlet of an exhaust duct of the closed hot aisle to refrigerate hot air discharged from the closed hot aisle to carry out air-cooling heat dissipation on the plurality of server cabinets.

11. The data center according to claim 10, wherein the circulating liquid-cooling system and the plurality of server cabinets positioned in the same device group are arranged side by side.

12. The data center according to claim 11, wherein the first device group and the second device group are arranged in parallel at intervals; and
a partition board is respectively provided between an end of the first device group and an end of the second device group, such that the closed hot aisle is formed between the first device group, the second device group, and the two partition boards.

13. The data center according to claim 12, wherein the circulating liquid-cooling system comprises at least a liquid inlet pipe, a liquid outlet pipe, and a plurality of liquid-cooling shunts;
the liquid inlet pipe and the liquid outlet pipe are connected to an external cooling device to refrigerate circulating liquids in the liquid inlet pipe and the liquid outlet pipe;
one end of each of the plurality of liquid-cooling shunts is communicated with the liquid inlet pipe, and other end of each of the plurality of liquid-cooling shunts is communicated with the liquid outlet pipe; and
each of the plurality of liquid-cooling shunts is connected in series with one end of a heat transfer component, and other end of the heat transfer component comes into contact with the primary heating source of the server cabinet.

14. The data center according to claim 13, wherein the external cooling device comprises one or more of a cooling tower, a dry cooler, and an evaporator.

15. The data center according to claim 13, wherein the air cooling device is connected to a first solenoid valve, and the circulating liquid-cooling system is connected to a second solenoid valve to control the external cooling device to operate independently of the circulating liquid-cooling system.

16. The data center according to claim 15, wherein the circulating liquid-cooling system further comprises a heat exchanger; and
the external cooling device exchanges heat with the circulating liquids in the liquid inlet pipe and the liquid outlet pipe through the heat exchanger.

17. The data center according to claim 16, wherein the heat exchanger is provided at one end of the first device group and one end of the second device group; and
an array cabinet is provided at other end of the first device group and other end of the second device group.

18. The data center according to claim 10, wherein a plurality of the combined device groups are provided, and the plurality of combined device groups are arranged in the closed area in a linear array.
